(19) United States
(12) Patent Application Publication
(10) Pub. No.: US 2011/0199728 A1
(43) Pub. Date: Aug. 18, 2011

(54) ENCLOSURE FOR DEMANUFACTURING

(76) Inventor: Jose Reyes, Newtown, PA (US)

(21) Appl. No.: 13/025,289

(22) Filed: Feb. 11, 2011

Related U.S. Application Data
(60) Provisional application No. 61/303,896, filed on Feb. 12, 2010.

(51) Int. Cl. G06F 1/18; H05K 5/02; A44B 18/00; H05K 7/12

(52) U.S. Cl. 361/679.31; 312/223.1; 24/442; 312/223.2; 361/726; 174/562

(57) ABSTRACT

An enclosure for an electronic device is described. In one implementation, an enclosure for an electronic device comprises a top wall operably connected to a bottom wall via side walls, a front wall operably connected to a rear wall via the side wall, a locking mechanism operably connected to the side walls, and a mechanism for operably connecting an internal component to the enclosure, wherein the mechanism is operably connected to at least one of the walls of the enclosure.

### CROSS-REFERENCE TO RELATED APPLICATION

This application claims the benefit of U.S. Provisional Application No. 61/303,896, filed Feb. 12, 2010, the entire disclosure of which is incorporated herein by reference.

### TECHNICAL FIELD

This application generally relates to enclosures for electronic devices. More particularly, this application relates to enclosures for use in electronic devices which optimally enables demanufacturing (disassembly).

### BACKGROUND

Recycling of obsolete and unwanted products generally provides benefits over alternatives such as disposal in landfills or incineration. Such recycling often benefits individuals, companies, and society both financially and by reducing the impact of disposal on the environment. Although usually applicable to most manufactured products, recycling is of particular interest for electronic products such as personal computers, displays, and printers because of the ever shortening life cycle before obsolescence of such electronic products.

There is an ever growing, large number of used and potentially obsolete computers and electronic devices. A reason for this may be the rapidly shortening life cycle of these products. Further, these products may be wholly or partially disassembled to remove parts which may have resale value. Refurbishing electronic products typically is more resource efficient than recycling. It is estimated in Computers and the Environment: Understanding and Managing their Impacts, Ruediger Juehr and Eric Williams (Eds), Lkumer Academic Publishers, United Nations University, 2003 that eighty percent of lifecycle energy for computers is consumed in the manufacturing phase. Therefore extending reuse by easy refurbishing of computers may dramatically increase environmental benefits. The remaining product typically is separated into basic materials such as plastics, precious metals, copper, steel, glass, etc. to be sold for their commodity values.

“Demanufacturing” as used and defined herein is the partial or complete disassembling of an electronic product into its basic internal components and subassemblies from the enclosure. Enclosures are mechanical assemblies usually having parts that are screwed, riveted, snapped, or otherwise fastened together at discrete points. Currently, the process of disassembling a computer, or more particularly, a laptop computer generally is a very time consuming manual process due to a need for removal of screws, fasteners, and glue bonded components. The use of screws historically has been required because of the danger to customers who may accidentally open up a computer and be exposed to voltage. Also, some manufacturers may void a warranty if a computer enclosure is opened or disassembled by anyone other than a qualified repairman.

Another trend in portable computers is their continued decrease in size and weight. This has led to creation of netbooks and or sub notebooks. There are many manufacturers who produce netbooks today. The trend of smaller, lighter and more powerful electronic products further create difficulties in demanufacturing efficiencies. This also creates further challenges in enclosure design. As more screws and fasteners are used for consumer safety and product durability, it creates a great inefficiency for product demanufacturing at end of life.

Furthermore, as power and sophistication of integrated circuit devices have increased, so have the level of electromagnetic interference (EMI) generated by such devices, i.e. integrated circuit devices unintentionally emit electromagnetic radiation (EMR) during operation that may cause interference with communication devices, such as telephones, radios and televisions. In order to prevent interferences, the enclosures often are shielded with an electrically conductive material to block the emission of EMR, which is emanating from the integrated circuit devices. By way of example, some methods for shielding the enclosure include: lining the plastic enclosure with a metallic foil such as aluminum, lining the plastic enclosure with sheet metal such as steel, and/or coating the inner surfaces of the plastic enclosure with a metallic material such as nickel or copper. Additionally, silicone based electrically conductive EMI gaskets may be formed in place between two parts of the enclosure before an enclosure is assembled.

Although current enclosures may work well, in many instances it would be desirable to provide enclosures that are highly secure for consumer protection, stronger and easier to demanufacture at end of life for providing enhanced environmental benefits.

### SUMMARY

In one implementation, an enclosure for an electronic device comprises a top wall operably connected to a bottom wall via side walls and a front wall operably connected to a rear wall via the side walls. A locking mechanism is operably connected to the side walls, and a mechanism for operably connecting an internal component to the enclosure, wherein the mechanism is operably connected to at least one of the walls of the enclosure.

In another implementation, an electronic device having an enclosure comprises an a top wall operably connected to a bottom wall via side walls, a front wall operably connected to a rear wall via the side walls, and a locking mechanism operably connected to the side walls. A storage device is operably connected to the inside of the enclosure via a hook and loop fastener. At least one circuit board is operably connected to the inside of the enclosure via a hook and loop fastener. A power supply is operably connected to the inside of the enclosure via a hook and loop fastener, wherein the power supply is electrically connected to at least one circuit board and the storage device. The circuit board is electrically connected to the storage device.

In yet another implementation, an electronic device having an enclosure comprises a top wall operably connected to a bottom wall via side walls, a front wall operably connected to a rear wall via the side walls, a locking mechanism operably connected to the side walls, and at least one circuit board operably connected to the inside of the enclosure via a hook and loop fastener.

### BRIEF DESCRIPTION OF THE DRAWINGS

In the drawings, which are discussed below, one or more implementations are illustrated. It is understood that the enclosure is not limited to the implementations depicted in the drawings herein, but rather it is defined by the claims appended hereto and equivalent structures.

FIG. 1 is a perspective of an electronic device in accordance with an exemplary implementation.

FIG. 2 is a broken away perspective diagram of an enclosure for the electronic device of FIG. 1 in accordance with an exemplary implementation.

FIG. 3A is a broken away perspective diagram of the enclosure of FIG. 2 showing a hook and loop fastener for adhering internal components without use or substantial use of screws.

FIG. 3B is a view of an exemplary hook and loop fastener with adhesive backing

FIG. 3C is a view of an exemplary hard drive attached to the inside of the bottom wall using a hook and loop fastener.

FIG. 4 is a perspective view of an electronic device showing placement of an exemplary implementation of a rapid release tool for opening the enclosure.

FIG. 5 is a cross-section view taken through line 5-5 shown in FIG. 4.

FIG. 6 is a block diagram showing an exemplary implementation of steps for demanufacturing an electronic device.

Like reference symbols in the various drawings indicate like elements.

### DETAILED DESCRIPTION

While the specification concludes with claims particularly pointing out and distinctly claiming subject matter, the enclosure for an electronic device will now be further described by reference to the following detailed description of exemplary implementations taken in conjunction with the above-described accompanying drawings. The following description is presented to enable any person skilled in the art to make and use the enclosure. Descriptions of specific implementations and applications are provided only as non-limiting examples and various modifications will be readily apparent to those skilled in the art. The general principles defined herein may be applied to other implementations and applications without departing from the spirit and scope of the enclosure. Thus, the enclosure is to be accorded the widest scope encompassing numerous alternatives, modifications, and equivalents consistent with the principles and features disclosed herein. For purpose of clarity, details relating to technical material that is known in the technical fields related to the enclosure have not been described in detail so as not to unnecessarily obscure the present application.

An improved enclosure arrangement for use in an electronic device especially when demanufacturing may be required for optimal efficiency during refurbishing or to separate the device into individual components for recycling.

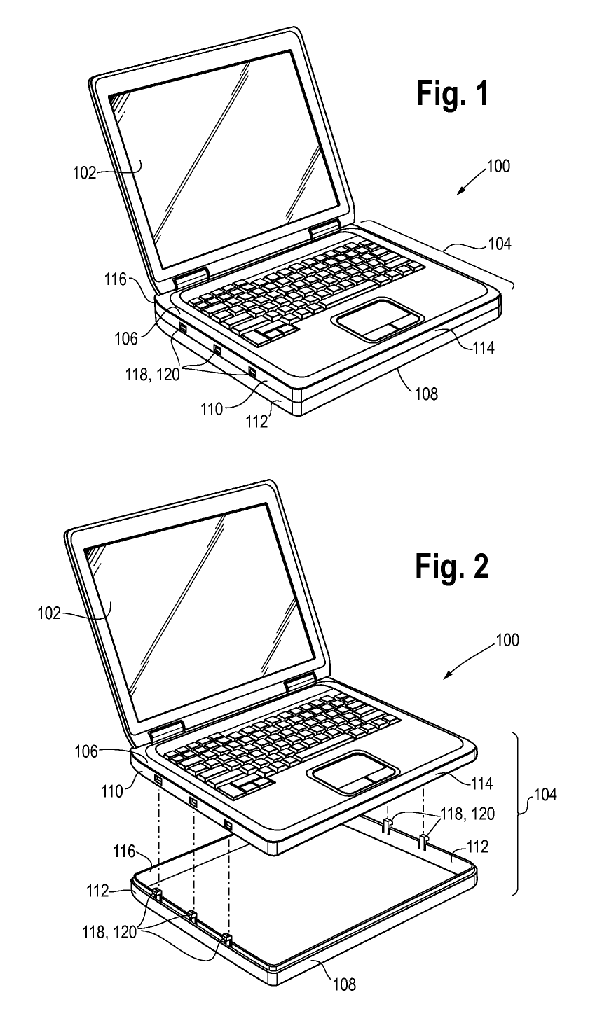

FIG. 1 is a perspective view of an electronic device 100 which includes a display 102 panel and an enclosure 104. As shown in the figure, the electronic device 100 is a portable computer. In some implementations, the electronic device 100 may be portable or not portable. In some implementations, the electronic device 100 may be a computer, a laptop or netbook or tablet computer, an mp3 player, a video player, a gaming device, a gaming console, a video recorder, an audio player, a portable communication device, a cell phone, a smartphone, a superphone, a personal digital assistant, a television, a monitor, or other electronic device. In some implementations, the enclosure 104 has a top wall 106 operably connected to a bottom wall 108 via side walls 110, 112 and a front wall 114 operably connected to a rear wall 116 via the side walls 110, 112. A locking mechanism 118 is operably connected to the side walls 110, 112, and a mechanism 300 for operably connecting an internal component 304 to the enclosure is operably connected to at least one of the walls of the enclosure 104. In some implementations, the side walls 110, 112 are integrated into the top, bottom, front, and/or rear walls 106, 108, 114, 116.

The enclosure 104 houses internal components 304 of the electronic device. In some implementations, the internal components 304 may be a power supply, a battery, storage device, and circuit board and/or other internal components typically found in electronic devices. In some implementations, the storage device may be a hard drive, read only memory (ROM), random access memory (RAM), flash memory, or any other device used for storing data or information. The internal components are generally surrounded at the peripheral region by a top wall and bottom wall that serve to support the internal components in their assembled position within the bottom wall. In some implementations, the internal components are electrically connected to each other. In some instances, integrated circuit chips on the circuit board, and/or other circuitry, may generate unwanted electrical emissions. In some implementations, a mechanism may be present for containing such electrical emissions. In some implementations, the mechanism for containing the electrical emissions may be at least one gasket operably connected to at least one of the walls of the enclosure. In some implementations, the mechanism for containing the electrical emissions may be lining the plastic enclosure with a metallic foil such as aluminum. In some implementations, the mechanism for containing the electrical emissions may be lining the plastic enclosure with sheet metal such as steel, and/or coating the inner surfaces of the plastic enclosure with a metallic material such as nickel or copper.

FIG. 2 is a broken away perspective diagram of an enclosure 104 for the electronic device 100 of FIG. 1 in accordance with one implementation. The top wall 106 and bottom wall 108 are configured to form a box-like structure having an internal volume when connected together. At least one locking mechanism 118 may be present to attach and lock the top and bottom walls 106, 108 together. In some implementations, a locking mechanism 118 is present on each side of the enclosure. In some implementations, little or no adhesive or glue is used at the seams because it is not optimal during demanufacturing for separating the top and bottom walls 106, 108 of the enclosure 104. In some implementations, the locking mechanism 118 may be a latched locking mechanism 120. In some implementations, the locking mechanism 118 may be a tab system, a magnet system, a press fit system, a pin, a snap-lock mechanism, a press-fit mechanism, a bracket-type mechanism, a slide-and-lock mechanism, a twist-and-lock or other friction-fit mechanism, a tongue-and-groove mechanism, a buckle mechanism, a joint, a hinge, or any other suitable mechanism for securing the top and bottom walls 106, 108 together.

In some implementations, the locking mechanism 118 allows for rapid opening of the enclosure 104 while preventing accidental release as observed in single lock mechanisms. An example of an accidental opening of an enclosure with a single lock mechanism is the dropping of a cell phone. Many times the back wall of the enclosure often will fall off when the cell phone is dropped. In some implementations, the locking mechanism 118 comprises a plurality of latched locking mechanisms 120. The plurality of latched locking mechanisms 120 described herein helps eliminate or prevent accidental exposure to the internal components of the portable computer or electronic device.

In some implementations, the enclosure 104 may be rapidly and safely opened during demanufacturing using a quick release tool 400. An exemplary implementation of the quick release tool 400 is shown in FIG. 4. In some implementations, the quick release tool 400 aligns with each locking mechanism 118 so that upon mating it unlocks the locking mechanism 118 so that the top wall 106 may be released from the bottom wall 108 with respect to the side wall where the mechanism is located. As shown in FIG. 4, a plurality of latched locking mechanisms 120 are located on at least one side of the enclosure and the quick release tool 400 is configured so that when it is aligned with and inserted into or contacts the latched locking mechanisms 120, the latched locking mechanisms 120 unlock.

The use of a plurality of latched locking mechanisms 120 with the optional quick release tool 400 enables a design that requires substantially little to no use of screws.

Screws often are a hindrance to demanufacturing and may make refurbishing or recycling of electronic products less than optimal.

The design disclosed in this application also may assist in worker health. Workers may develop carpal tunnel syndrome because of extensive use of screw drivers and the constant repetitive twisting motion required to remove screws from electronic products. To open the enclosure described herein will take considerably less time versus unscrewing or tearing apart glued or bonded or electrically welded enclosures. Product manufacturers may void a warranty if a consumer opens up the enclosure exposing internal components. The plurality of latched locking mechanisms prevents accidental opening. In some implementations, the special quick release tool may be required for deliberately opening the enclosure.

It is understood by one skilled in the art that the plurality of locking mechanisms 118 may be designed differently from the design shown in FIG. 5. As a non-limiting example, locking mechanisms such as cantilever, U-shaped cantilever and L-shaped cantilever mechanisms may be used. Also, one skilled in the art understands that use of a double, triple, quadruple, or an additional number of latches per locking mechanism may be used if additional clamping force of the top wall to the bottom wall is desired. Furthermore, one skilled in the art understands that more than a plurality of latched locking mechanisms 120 may be used. As a non-limiting example, each side of the enclosure 104 may have locking mechanisms 118 and a corresponding optional quick release tool or tools 400 for optimal demanufacturing.

The enclosure 104 may be made from a variety of materials. In some implementations, the enclosure material may be one or a combination of a hard or rigid, substantially hard or rigid, semi rigid, or non-elastomeric material such as polycarbonate or the like. The enclosure material may be a metal such as aluminum or metal alloys, or it may be plastic such as a high density polyethylene, low density polyethylene, polypropylene, thermoplastic, amorphous thermoplastic or other resin or polymer or combinations thereof.

Non-limiting examples of thermoplastics include, but are not limited to, acrylonitrile butadiene styrene (ABS), liquid crystal polymer (LCP), polyamide (PA or nylon), polyamide-imide (PAI), polyaryletherketone (PAEK or ketone), polybutylene terephthalate (PBT), Polyethylene terephthalate (PET), polycyclohexylene dimethylene terephthalate (PCT), polyester, polyethylene, polyetheretherketone (PEEK), polyetherketoneketone (PEKK), polyethersulfone (PES), polysulfone, polyimide (PI), polyether imide (PEI), polylactic acid (PLA), polymethylpentene (PMP), polyphenylene oxide (PPO), polyphenylene sulfide (PPS), polyphthalamide (PPA), acetal, styrene-acrylonitrile (SAN), and polycarbonate ABS blends. Blends of the above may also be suitable. Thermoplastics used for the enclosure should meet consumer testing requirements for use in electronic products.

One skilled in the art understands that the use of decorative coatings may be applicable. Furthermore, one skilled in the art also understands that portions of the enclosure 104 or all of the enclosure 104 may be polished to have a high gloss finish or a substantially high gloss finish.

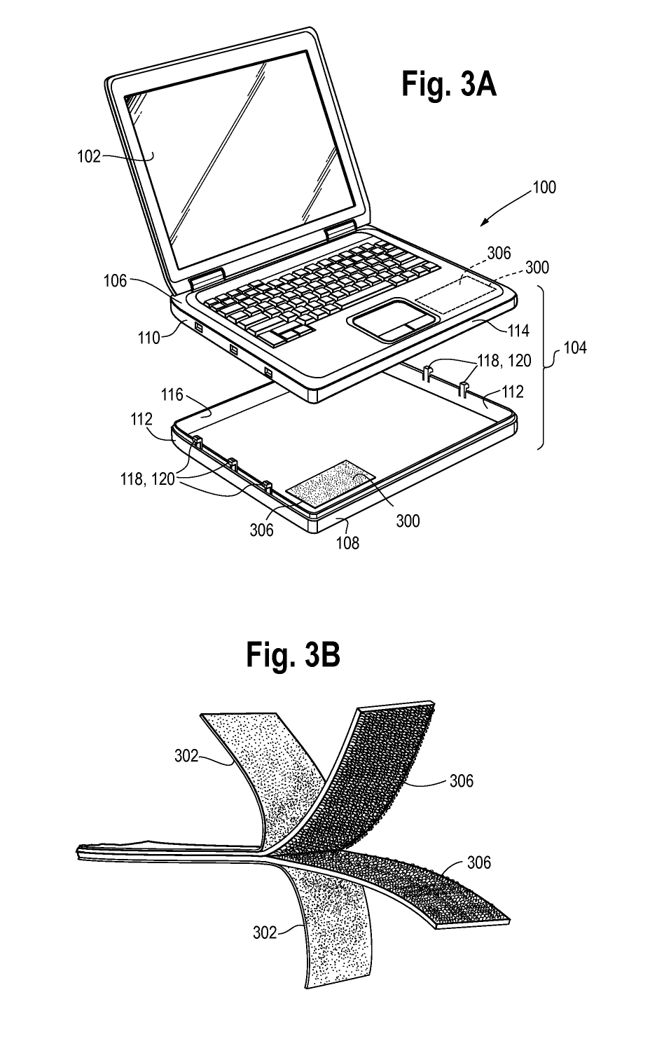

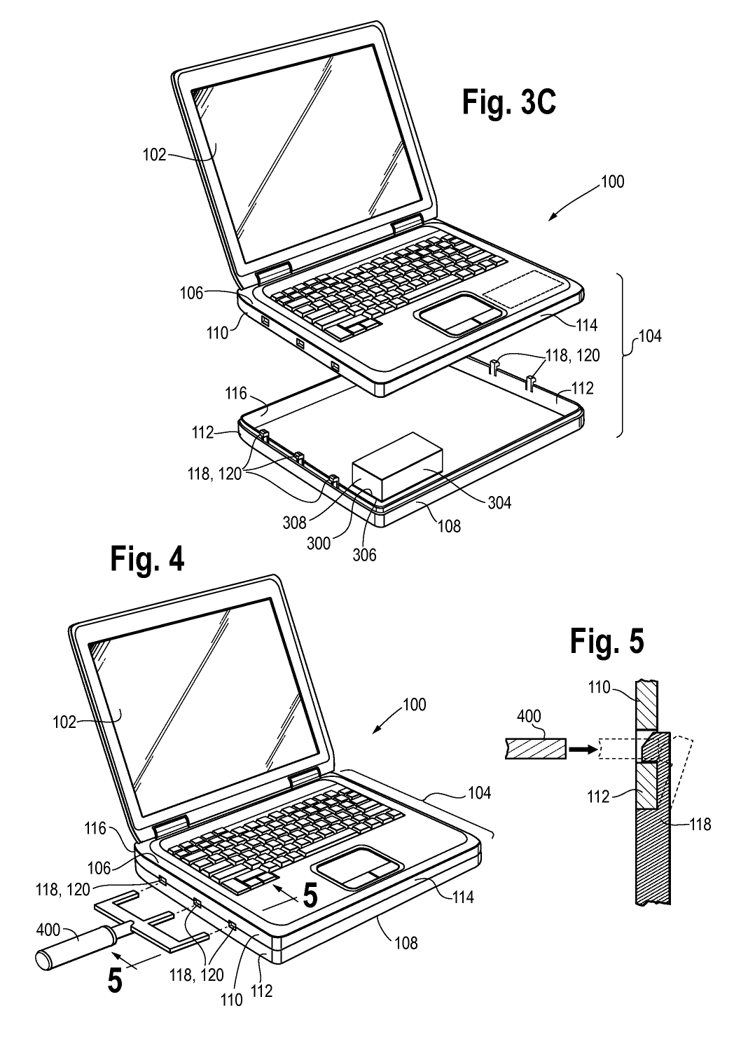

FIG. 3A shows a broken away perspective diagram of enclosure 104 of FIG. 2 showing example locations for adhering internal components with a hook and loop fastener, a screw, and/or glue. In some implementations, hook and loop fasteners 306 may be used to operably attach internal components to the enclosure 104. Internal components 304 may include, but are not limited to, a hard drive, a circuit board, input/output support devices, a microprocessor, a battery, memory, etc. As shown in FIG. 3B, on the back of each hook and loop fastener 306 is an adhesive 302 which enables the hook and loop fastener 306 to be attached to at least one of the inside walls of the enclosure 104 of FIG. 3A. In some implementations, the hook and loop fastener 306 may be attached to the inside top wall 106, the inside bottom wall 108, and/or at least one side wall 110, 112 of the enclosure of FIG. 3A. Unlike screws or glue, or metal fastener attachments, use of hook and loop fasteners 306 enable the internal components to be rapidly removed for disassembly during demanufacturing. Screws, metal fasteners, glue, electronic welding and the like are not optimal attachment methods for demanufacturing because they may lead to slow removal processes and, when screws need to be removed, also may lead to carpal tunnel syndrome in demanufacturing workers due to the repetitive nature of constantly turning screw drivers. Nevertheless, in some implementations, screws, metal fasteners, glue, electronic welding and the like may be used in conjunction with or in addition to hook and loop fasteners 306.

Using the enclosure 104 described in this application that incorporates hook and loop fasteners 306, during refurbishing of an electronic device 100, one simply applies a mating hook and loop fastener 306 on the internal component 304 being replaced and attach it to the corresponding hook and loop fastener 306 on the enclosure 104 location of the prior internal component. FIG. 3C shows a storage device 308 such as a hard drive attached to the inside bottom wall 108 of the enclosure 104 using a hook and loop fastener 306.

The use of hook and loop fasteners 306 offers the opportunity to install and rapidly remove internal components similar to a “plug and play” manner. One benefit of this is considerable reduction in the labor to disassemble electronic products and improving worker health. Because of the ease and optimal design for demanufacturing, the enclosure 104 enables greater efficiency in refurbishing, upgrading or recycling of electronic products. Environmental benefits likely will be substantial due to better energy utilization and material conservation as well as enhanced worker health.

In another implementation of the enclosure 104, the hook and loop fasteners 306 may be made from conductive material for shielding electronic emissions. The hook and loop fasteners 306 may be made from nylon or polyester materials. Addition of conductive materials or conductive coatings to the nylon or polyester will make the hook and loop fasteners conductive. This may help arrest electromagnetic emissions. In so doing the hook and loop fasteners 306 serve as both an attaching mechanism for internal components and an EMR shielding agent. This helps reduce some of the EMR agents in conventionally used electronic products. Furthermore, the demanufacturing is more optimal because less material may be required versus conventional electronic products. Minimization of materials is good for the environment.

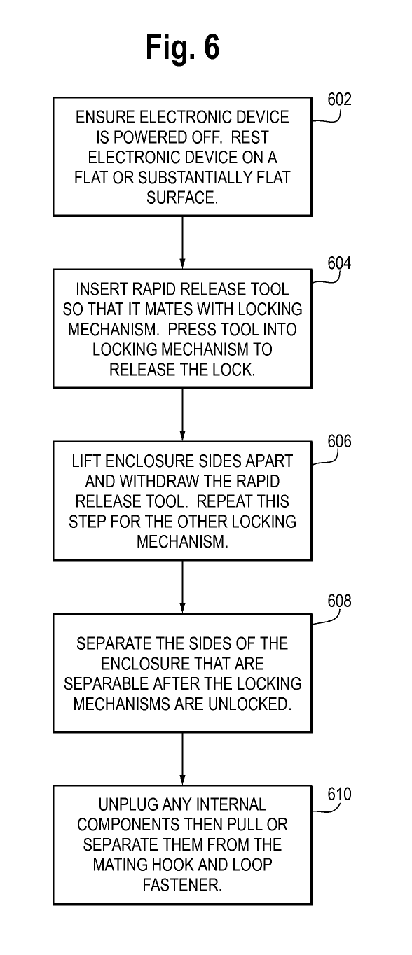

FIG. 6 shows an implementation of steps for demanufacturing an electronic device having an enclosure as described herein. Ensure the electronic device is powered off, e.g., the power is not “on,” and optionally rest the electronic device on a flat or substantially flat surface 602. Insert an optional rapid release tool so that it mates with the enclosure's locking mechanism 604. Press the rapid release tool into the locking mechanism to release the lock 604. Lift the enclosure sides apart which were connected by the now unlocked locking mechanism and withdraw the rapid release tool 606. Repeat this step for other locking mechanisms present on the enclosure 606. Separate the sides of the enclosure that are separable after the locking mechanisms are unlocked 608. In some implementations, only one locking mechanism is used and the sides of the enclosure may be separated after the only locking mechanism is unlocked. In some implementations, the top wall of the enclosure is separable from the bottom wall of the enclosure. Unplug any internal components then pull or separate them from the mating hook and loop fastener 610. The method described herein for disassembly permits quicker disassembly of electronic components compared to the time for disassembling conventional electronic products.

One skilled in the art understands that mechanisms other than hook and loop fasteners which meet the purposes described in this application may be used to operably attach internal components to the enclosure. As a non-limiting example, heat sealable fabrics which can be attached to the inside of the enclosure 104 and to an internal component 304 for attaching said component 304 to the enclosure 104 may be used.

A number of implementations have been described. Nevertheless, it will be understood that various modifications may be made without departing from the spirit and scope of the disclosures in this application. As a non-limiting example, additional components may be added to those described above, or components may be removed or rearranged. It is understood by one skilled in the art that the connections and attachments described in this disclosure may be direct or indirect connections and attachments, respectively.

What is claimed is:

1. An enclosure for an electronic device comprising:
a top wall operably connected to a bottom wall via side walls;
a front wall operably connected to a rear wall via the side walls;
a locking mechanism operably connected to the side walls; and
a mechanism for operably connecting an internal component to the enclosure, wherein the mechanism is operably connected to at least one of the walls of the enclosure.

2. The enclosure of claim 1, wherein the locking mechanism is a latched locking mechanism.

3. The enclosure of claim 1, wherein the locking mechanism is a cantilever system.

4. The enclosure of claim 1, wherein the mechanism for operably connecting the internal component to the enclosure comprises a hook and loop fastener.

5. The enclosure of claim 1, wherein the mechanism for operably connecting the internal component to the enclosure comprises at least one of a hook and loop fastener, a screw, and glue.

6. The enclosure of claim 1, wherein the mechanism for operably connecting the internal component to the enclosure comprises a hook and loop fastener and at least one of a screw and glue.

7. The enclosure of claim 1, further comprising a mechanism for containing electrical emissions operably connected to at least one of the walls.

8. The enclosure of claim 1, further comprising a quick release tool configured to align and mate with and unlock the locking mechanism.

9. The enclosure of claim 1, wherein the electronic device is a computer.

10. The enclosure of claim 1, wherein the electronic device is portable.

11. The enclosure of claim 1, wherein the side walls are integrated into at least one of the top wall, bottom wall, front wall, and rear wall.

12. An electronic device having an enclosure comprising:
a top wall operably connected to a bottom wall via side walls;
a front wall operably connected to a rear wall via the side walls;
a locking mechanism operably connected to the side walls;
a storage device operably connected to the inside of the enclosure via a hook and loop fastener;
at least one circuit board operably connected to the inside of the enclosure via a hook and loop fastener; and
a power supply operably connected to the inside of the enclosure via a hook and loop fastener, wherein
the power supply is electrically connected to the at least one circuit board and the storage device, and
the at least one circuit board is electrically connected to the storage device.

13. The electronic device of claim 12, wherein the hook and loop fastener is electrically conductive.

14. The electronic device of claim 12, wherein the locking mechanism comprises a latched locking mechanism.

15. The electronic device of claim 12, wherein the locking mechanism comprises a cantilever system.

16. The electronic device of claim 12, wherein the electronic device is a computer.

17. The electronic device of claim 12, wherein the electronic device is portable.

18. The electronic device of claim 12, further comprising a quick release tool configured to align and mate with and unlock the locking mechanism.

19. The electronic device of claim 12, wherein the side walls are integrated into at least one of the top wall, bottom wall, front wall, and rear wall.

20. The electronic device of claim 12, further comprising a mechanism for containing electrical emissions operably connected to at least one of the walls.

21. An electronic device having an enclosure comprising:
a top wall operably connected to a bottom wall via side walls;
a front wall operably connected to a rear wall via the side walls;
a locking mechanism operably connected to the side walls; and
at least one circuit board operably connected to the inside of the enclosure via a hook and loop fastener.
